(19) United States
(12) Patent Application Publication
(10) Pub. No.: US 2026/0213649 A1
(43) Pub. Date: Jul. 23, 2026

(54) DC-DC VOLTAGE CONVERTER DEVICE AND METHOD FOR OPERATING A DC-DC VOLTAGE CONVERTER DEVICE

(71) Applicant: Robert Bosch GmbH, Stuttgart (DE)

(72) Inventor: Gholamabas Esteghlal, Stuttgart-Weilimdorf (DE)

(21) Appl. No.: 19/131,993

(22) PCT Filed: Oct. 4, 2023
(86) PCT No.: PCT/EP2023/077433

§ 371 Date: May 22, 2025

(30) Foreign Application Priority Data
Nov. 22, 2022 (DE) 10 2022 212 428.6

(51) Int. Cl. H02M 1/44; G01R 19/00; H02M 1/00; H02M 1/14; H02M 1/36

(52) U.S. Cl. CPC H02M 1/44; G01R 19/0053; G01R 19/0084; H02M 1/0012; H02M 1/143; H02M 1/36

(57) ABSTRACT

The invention relates to a DC-DC converter assembly having an operating mode in which an input voltage is sampled at a high sampling rate and the control variable for controlling a DC-DC converter can be adapted on the basis of the rapidly sampled input voltage. In particular, the input voltage that is sampled with a high sampling rate can be processed in a separate computing unit

### BACKGROUND

The present invention relates to a DC-DC converter device and to a method for operating a DC-DC converter device.

Fully or at least semi-electrically powered vehicles as a rule have an electrical energy store, for example a traction battery. This traction battery provides the electrical energy required in order to propel the electric vehicle. The traction battery as a rule supplies an output voltage of multiple hundreds of volts and supplies a so-called high-voltage network of the vehicle. Moreover, such a vehicle as a rule comprises multiple electrical consumers supplied at a lower electrical voltage via a low-voltage network. For coupling the high-voltage network and the low-voltage network, and in particular for transferring electrical energy from the high-voltage network to the low-voltage network, so-called DC-DC converter can be provided, which convert an electrical DC voltage from the high-voltage network into a DC voltage for the low-voltage network.

Publication DE 2009 028 147 A1 describes a circuit arrangement for an on-board electrical system of an electric vehicle, wherein a DC-DC converter is provided for coupling between two on-board electrical system parts.

### SUMMARY

The present invention discloses a DC-DC converter device and a method for operating a DC-DC converter device with the features of the independent claims. Further advantageous embodiments are the subject-matter of the dependent claims.

The following is provided:

A DC-DC converter device having a DC-DC converter, a voltage control, a current control, a pilot device and a control device. The voltage control is configured to determine a first control variable for the DC-DC converter using a target value for the output voltage of the DC-DC converter and a measured value for the output voltage of the DC-DC converter. The current control is configured to determine a second control variable for the DC-DC converter using a current control variable and a momentary current value of the DC-DC converter. The pilot device is configured to determine a third control variable using the target value for the output voltage of the DC-DC voltage converter and a filtered measured value for the input voltage of the DC-DC voltage converter. For example, filtering the measured value for the input voltage may include low pass filtering or time averaging. The control device is configured to control the DC-DC converter using a combination of the first control variable, the second control variable and the third control variable in a first operating mode. Furthermore, the control device is configured to control the DC-DC converter using a combination of the first control variable, the second control variable and a measured value for the input voltage of the DC-DC converter in a second operating mode.

The following is furthermore provided:

A method for operating a DC-DC converter device with at least one DC-DC converter. The method comprises a step of determining a first control variable for the DC-DC converter. The first control variable is determined in particular using a target value for the output voltage of the DC-DC converter and a measured value for the output voltage of the DC-DC converter. Furthermore, the method comprises a step of determining a second control variable for the DC-DC converter. The second control variable is determined in particular using a target value or a predetermined maximum current value in the DC-DC voltage converter and a momentary current value of the DC-DC converter. Furthermore, the method comprises a step of determining a third control variable using the target value for the output voltage of the DC-DC converter and a filtered measured value for the input voltage of the DC-DC converter. For example, the filtering may comprise mean averaging over a predetermined period of time or low pass filtering. Moreover, the method comprises a step of controlling the DC-DC converter in a first operating mode or a second operating mode. In the first operating mode, the DC-DC converter is controlled using a combination of the first control variable, the second control variable and the third control variable. In the second operating mode, the DC-DC converter is controlled using a combination of the first control variable, the second control variable and a measured value for the input voltage of the DC-DC converter.

### Advantages of the Invention

The present invention is based on the finding that an electrical voltage at the input of a DC-DC voltage converter can be subjected to interference, in particular so-called ripple. Thus, with a constant transformation ratio between the input DC voltage and the output DC voltage, the interference of the electric voltage at the input of the DC voltage converter is transmitted to the electric voltage at the output of the DC voltage converter according to the transformation ratio. On the other hand, however, a constant output voltage of the DC-DC converter that is as interference-free as possible is desirable for numerous applications.

However, conventional controls for stabilizing the output voltage of a DC-to-DC converter, in particular controls based on microcontrollers, are only able to follow the rapid voltage changes of interference at the input of the DC-to-DC converter to a very limited extent.

It is therefore an idea of the present invention to take this realization into account and to create a control structure that is able to follow voltage changes, in particular higher frequency interference superimposed on a DC voltage, at a sufficient speed to compensate for the voltage fluctuations and thus to be able to provide a DC voltage at the output of the DC converter which is as constant as possible.

According to the invention, in addition to a conventional control based on a microcontroller, a further control is provided for the voltage control, which can follow voltage variations very quickly. In this way, it is possible to also follow higher frequency and fast voltage changes at the input of a DC converter and to compensate for them. Thus, the constancy of the supplied output voltage on the DC-DC converter can be improved. In addition, the risk of vibrations in the control system due to higher frequency interference is also reduced.

In particular, it is possible to build on existing control structures and adapt them easily by adding the additional control component to the voltage control. This simplifies the construction and design of such DC-DC converter assemblies.

For the voltage control of the higher frequency interference, very fast operating components can in particular be used. These may form a computational unit that can execute instructions very quickly in parallel with a conventional microcontroller. In this way, small portions of software may be outsourced to such additional components, for example to calculate the corresponding control signals to compensate for higher frequency interference.

Such a control structure can thus process low-frequency or average voltage values in a conventional manner and provide control variables based on this. Moreover, the higher-frequency interference portions, such as voltage ripple, can be detected by means of suitable components that operate faster and, based thereon, a further control variable can be provided that compensates for this interference.

The DC-DC converter can thus be controlled in a manner to compensate for the interferences on the input side and to provide as constant a DC voltage as possible on the output side.

In order to furthermore enable a stable start-up of such a control structure, a plurality of operating modes may be provided in the control of a DC-DC converter according to the invention. In a first operating mode, for example, the DC-DC voltage converter can first be controlled without compensating for higher frequency portions. Thus, the risk that vibrations or instabilities can occur during start-up or initialization decreases. If an at least approximately stationary state, for example a quasi-stationary state, is subsequently reached, it is possible to switch to a further operating mode in which the additional control is activated based on a quick evaluation of the input voltage. This further operating mode may be maintained, for example, as long as the input voltage, in particular the low-frequency portions of the input DC voltage, are at an at least approximately constant level. If, for example, there are voltage jumps in the input voltage or any other significant disruptions in the operating behavior, it is possible to switch at least temporarily from this further operating mode to the initial operating mode, in which the compensation of high-frequency portions in the input voltage is suspended.

According to one embodiment, the control device is configured to control the DC-DC converter in the second operating mode using a measured value for an output current of the DC-DC converter. In this way, for example, influences can also be compensated very quickly by load jumps on the output side of the DC-DC voltage converter.

According to one embodiment, the first pilot device is configured to provide a control signal to the control device. Furthermore, the control device is configured to set either the first operating mode or the second operating mode using the control signal from the pilot device. In this way, the pilot device can activate or deactivate the compensation of high-frequency interference portions in the input voltage. For example, during initialization or start-up, the pilot device can initially deactivate the compensation of the high-frequency interference portions until a quasi-stationary state, as a state with at least approximately constant conditions, is reached. Furthermore, for example, even with significant fluctuations in the input voltage or other events, the compensation of high-frequency interference can be deactivated at least temporarily until stable operating conditions have again adjusted in the DC-DC converter device.

According to one embodiment, the control device is configured to detect the measured value for the input DC voltage at a sampling rate that is higher than a sampling rate for detecting the measured value of the input DC voltage for the pilot device. The control device can in particular be designed to detect frequency portions in the DC input voltage up to at least 10 kHz. On the one hand, this means that faults or voltage fluctuations, such as voltage ripple or similar, can also be detected and compensated for in the control device. On the other hand, simple and inexpensive components can be used for the detection and processing of the input voltage in the pilot device, which only have to be designed for a lower sampling rate.

According to one embodiment, the DC-DC converter device is configured to perform the determination of the first control variable, the second control variable and the third control variable, as well as the controlling the DC-DC converter in the first operating mode using a first computing means. In this case, the first computing device can comprise at least one microcontroller. Furthermore, the DC-DC converter device may be configured to control the DC-DC converter in the second operating mode using a second computing device. In this case, the second computing device can be configured to receive and process the measured value for the input voltage of the DC-DC voltage converter. In particular, the second computing device may comprise, for example, a multi-channel sequencer. In principle, however, any other components are also possible as second computing devices, which, in addition to the microcontroller used for the first device, enable very fast processing of software components.

According to one embodiment, the DC-DC converter device comprises multiple DC-DC converters. Thereby a separate current control can be provided for each DC-DC converter of the DC-DC converter device. Likewise, a separate control device can be provided for each DC-DC converter of the DC-DC converter device. Furthermore, a common voltage control can be provided for all DC-DC converters of the DC-DC converter device. Likewise, a common pilot device can be provided for all DC-DC converters of the DC-DC converter device. This way, for example, the performance of the DC-DC converter device can be increased by parallel switching of multiple DC-DC converters.

The above embodiments and further developments can be combined with one another in any desired manner insofar as advantageous. Additional embodiments, further developments, and implementations of the invention also include inventive feature combinations not described or explicitly specified hereinabove or hereinafter with respect to exemplary embodiments. The skilled person will in particular also add individual aspects as improvements or additions to the respective basic forms of the invention.

### BRIEF DESCRIPTION OF THE DRAWINGS

Further features and advantages of the invention are explained hereinafter with reference to the drawings. Shown are:

FIG. 1: a schematic view of a DC-DC converter device with a control device according to one embodiment;

FIG. 2: a schematic view of a DC-DC converter device with a control device according to a further embodiment; and FIG. 3: a flow chart that forms the basis for a method according to one embodiment.

In the drawings, identical reference numerals denote identical or functionally identical components, unless stated otherwise.

### DETAILED DESCRIPTION

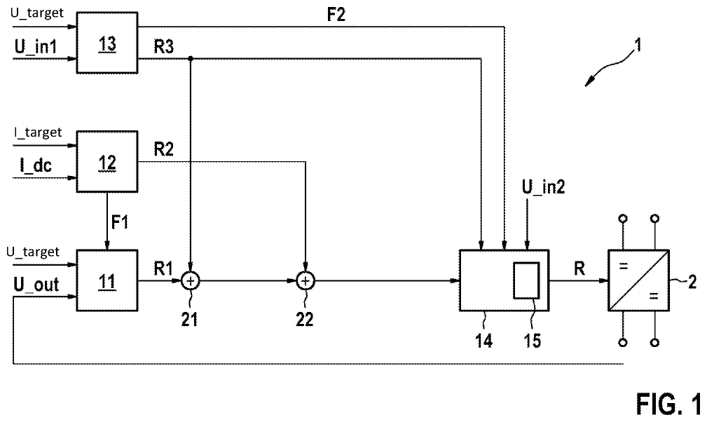

FIG. 1 shows a block diagram that forms the basis for a DC-DC converter device 1 according to one embodiment. In the embodiment shown here, the DC-DC converter device 1 comprises a DC-DC converter 2.

The DC-DC converter 2 converts a DC voltage supplied at the input side into an output DC voltage. In particular, the input DC voltage may be greater than the output DC voltage, for example. The DC voltage converter 2 can be operated in a step-down converter mode (buck mode) for example.

For example, the DC-DC converter 2 can be a so-called active clamp flyback DC-DC converter. However, because the basic structure of such a DC-DC converter is known in particular also from flyback DC-DC converters, this will not be discussed in further detail.

To regulate or control the DC-DC converter 2, a control variable R, for example in the form of a duty cycle for a pulse width modulated (PWM) control, can be provided to the DC-DC converter 2. The basic principle of a DC-DC converter with pulse width modulated control is hereby also assumed to be known and will not be explained in further detail.

To generate the control variable R, the DC voltage converter device 1 comprises a voltage control 11, a current control 12, a pilot device 13, and a control device 14.

The voltage control 11 generates a first control variable R1. For this purpose, the voltage control 11 compares a value of the output DC voltage U_out to a predefined target value U_target. For example, this target value U_target can be a value for the target voltage.

The current control 12 generates a second control variable R2, which is determined, for example, on the basis of the electric current 1_dc in the DC-DC converter 2. For example, an input current and/or an output current can be detected on the DC voltage converter 2 and provided to the current control 12. For example, the current control 12 may monitor the electrical current into the DC-DC converter 2, out of the DC-DC converter 2 or within the DC-DC converter 2, and, for example, limit the current to a maximum value. If a predetermined maximum value for the electrical current is exceeded, a second control variable R2 can be output from the current control 12 in order to counteract a further current increase. Furthermore, the current control 12 may output an activation signal F1, which, for example, may be provided to the current control 11. As a result, the voltage control 11 may be deactivated set to a state in which the voltage control 11 does not counteract the current limit by the current control 12.

In addition to the primary voltage control 11, a pilot device 13 is also provided. This pilot device 13 can, for example, determine a third control variable R3 based on the input DC voltage U_in, the target voltage U_target, as well as optionally electrical currents 1_dc within the DC-DC voltage converter 2, at the input and/or output of the DC-DC converter 2.

The first control variable R1, the second control variable R2 and the third control variable R3 can be combined with one another and this combination can be provided to the control device 14. For example, the first control variable R1 can first be combined by the voltage control 11 and the third control variable R3 by the pilot device 13 in a first summing element 21. This sum can then be combined with the second control variable R2 from the current control 12 in the second summing element 22. The result of this combination may be used by the control device 14 to control the DC link converter 2 in a first operating mode.

By means of such a circuit concept, a third control variable R3 can first be generated by means of the pilot device 13, which is suitable for generating an output voltage by means of the DC voltage converter 2 that lies in the range of the predetermined target voltage U_target. For this purpose, the input voltage at the input of the DC-DC voltage converter 2 can be digitally detected at a first sampling rate, for example, and processed as the first measured value U_in1 in the pilot device 13. In particular, filtering of the input voltage detected in the DC-DC voltage converter 2 is also possible for this processing. Such filtering may be, for example, mean averaging over a predetermined period of time, low pass filtering at a predetermined threshold frequency, or the like. In principle, such filtering may also be carried out in other suitable ways. For example, the voltage may also be detected at a correspondingly low sampling rate.

Furthermore, as already described above, the voltage control 11 can compare the measured value U_out of the output voltage with the predetermined target or target voltage U_target and then output the first control variable R1 to correct any deviations between the target voltage U_target and the actual output voltage U_out. In this way the voltage control 11 only has to correct small deviations in order to adjust the third control variable R3, which was predetermined by the pilot device 13, to a value by means of the first control variable R1 so that the voltage at the output of the DC-DC converter 2 corresponds to the predetermined target value U_target.

In addition, the current control 12 may monitor and limit the electrical currents on the DC-DC voltage converter 2 already mentioned.

The above-mentioned processing for the voltage control 11, current control 12 and pilot device 13 may be carried out, for example, by means of one or more microcontrollers. For example, the voltage control 11, current control 12, and pilot device 13 may be implemented as software modules executed by means of a microcontroller. If necessary, the previously described functions of the control device 14, which performs the control of the DC-DC voltage converter 2 based on the combination of the first control variable R1, the second control variable R2 and the third control variable R3, can also be performed by means of the microcontroller.

However, such a microcontroller may not process the data quickly enough to respond quickly enough to high-frequency influences, such as voltage ripple in the input voltage. Therefore, a second operating mode is provided in the DC-DC converter device 1, in which high-frequency influences, such as the mentioned voltage ripple, can be responded to quickly enough.

In this second operating mode, the control device 14 may detect the electrical voltage at the input of the DC-DC converter 2 at a high sampling rate, for example at a sampling frequency of 10 kHz or more. In particular, the sampling rate for these second measured values U_in2 of the input voltage on the DC-DC voltage converter 2 can be higher than the sampling rate for the first measured values U_in1 of the input voltage, which are processed by the pilot calculation 13.

In this second operating mode, the control device 14 may use the second measured values U_in2, which have been detected at a high sampling rate, to generate the control variable R for controlling the DC-DC converter 2. In particular, in this second operating mode, the control device 14 may generate the control variable R for controlling the DC-DC voltage converter 2 using the first control variable R1, the second control variable R2 and the measured value U_in2 of the quickly sampled input voltage of the DC voltage converter 2. For this purpose, for example, the third control variable R3 can be provided to the control device 14, so that the control device 14 subtracts the third control variable R3 from the provided combination of the first control variable R1, the second control variable R2 and the third control variable R3 and then supplements this result with a further control variable based on the measured value U_in2 of the quickly sampled input voltage.

If necessary, it is also possible for the control device 14 to generate the control variable R for controlling the DC-DC converter 2 additionally based on a quickly sampled measured value for the output current on the DC-DC converter 2. In this way, load jumps or the like can also be compensated for very quickly.

The processing described above for determining a control variable R for controlling the DC-DC voltage converter 2 to compensate for fast, high-frequency influences can be carried out by means of an additional computing unit 15. In particular, this additional computing unit 15 may be a fast operating processing unit that performs the required processing steps outside of a microcontroller described above. For example, for this additional computing unit 15, a so-called multi-channel sequencer MCS can be employed, which can execute instructions as a computing unit parallel to the microcontroller. For example, such an MCS is capable of performing predetermined portions of software outside the microcontroller at a very high processing speed.

The concept described above thus makes it possible, in the second operating mode, to take into account very rapid changes in the input voltage, such as can those that can occur due to voltage ripple or the like, when controlling the DC-DC voltage converter 2 and thus to control the DC-DC voltage converter 2 such that these high-frequency influences are not, or at least not completely, reflected on the output side of the DC voltage converter 2.

Moreover, in the first operating mode, this processing of fast changes in the input voltage may be suspended. In this way, for example, the stability of the DC voltage converter device 1 can be increased when the device is started up or initialized. For this purpose, for example, a further control signal F2 can be output by the pilot control device 13 and provided to the control device 14, which indicates the respective operating mode to the control device 14. If, for example, the pilot direction 14 detects in the analysis of the slowly sampled or filtered input voltage U_in1 that significant variations occur in the input voltage, the first operating mode may initially be set. These significant variations may be voltage jumps, for example, in particular when switching on. If, on the other hand, an at least approximately stationary state (quasi-stationary state) is present, it is then possible to switch to the second operating mode in order to be able to compensate for fast, high-frequency influences.

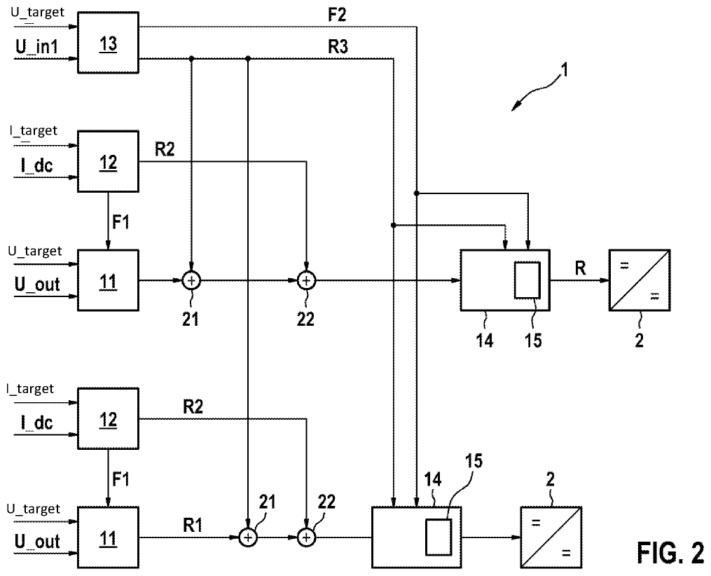

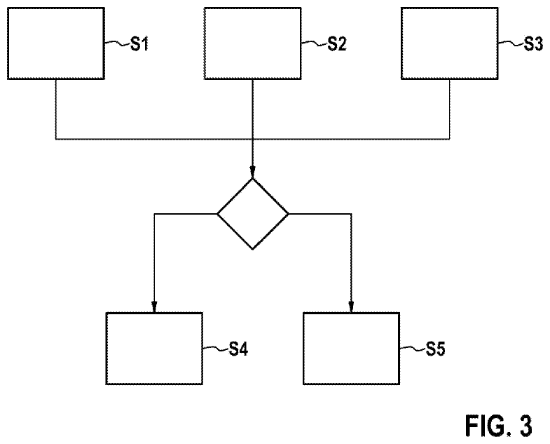

FIG. 2 shows a schematic illustration of a DC-DC converter device 1 according to a further embodiment. The embodiment shown in FIG. 2 differs from the above-described embodiment in particular in that a plurality of DC-DC converters 2 are provided. By connecting a plurality of DC-DC converters 2 in parallel, the overall power for the DC-DC converters can be increased, for example. As far as applicable, all embodiments previously made in connection with FIG. 1 also apply.

As can be seen in FIG. 2, a common pilot device 13 and a common voltage control 11 may be provided for the DC-DC converter 1 with a plurality of DC-DC converters 2. In addition, an individual voltage control 12 and an individual control device 14 may be provided for each voltage converter 2.

FIG. 3 shows a flowchart as it underlies a method for operating a DC-to-DC converter device 1 according to one embodiment. In principle, the method can comprise any of the steps previously described in connection with the DC-DC converter device 1. Analogously, the DC-DC converter device 1 described above can also comprise any desired and suitable components that are necessary for implementing the method described hereinafter.

The method comprises a step S1 of determining a first control variable R1 for the DC-DC converter 2. The first control variable R1 can be determined in particular using a target value U_target for the output voltage of the DC-DC converter 2 and a measured value U_out for the output voltage of the DC-DC converter 2.

Furthermore, the method comprises a step S2 of determining a second control variable R2 for the DC-DC converter 2. The second control variable R2 can be determined in particular using a current control variable 1_target and a momentary current value 1_dc of the DC-DC converter 2.

Furthermore, the method comprises a step S3 for determining a third control variable R3. The third control variable R3 is determined in particular using a target value U_target for the output voltage of the DC-DC converter 2 and a measured value U_in1 for the input voltage of the DC-DC converter 2.

Moreover, the method comprises a step S4 of controlling the DC-DC converter 2 in a first operating mode. In this first operating mode, the control is carried out in particular using a combination of the first control variable R1, the second control variable R2 and the third control variable R3.

Alternatively, in a step S5, the method may control the DC voltage converter 2 in a second operating mode. In this second operating mode, the DC-DC converter 2 is controlled using a combination of the first control variable R1, the second control variable R2, and a quickly sampled measured value U_in2 for the input voltage of the DC-DC converter.

As already mentioned, the DC-DC converter 2 can be initially controlled in the first operating mode after an initialization. Furthermore, the control of the DC-DC converter 2 may be switched to the second operating mode, for example after a quasi-stationary operating state has been set in the DC-DC converter.

In summary, the present invention relates to a DC-DC converter assembly having an operating mode in which an input voltage is sampled at a high sampling rate and the control variable for controlling a DC-DC converter can be adjusted on the basis of the rapidly sampled input voltage. In particular, the input voltage that is sampled with a high sampling rate can be processed in a separate computing unit.

1. A DC-DC voltage converter assembly (1), having:
a DC-DC converter (2) configured so as to convert an input DC voltage into an output DC voltage;
a voltage control (11) configured to determine a first control variable (R1) for the DC-DC converter (2) using a target value (U_target) for the output voltage of the DC-DC converter (2) and a measured value (U_out) for the output voltage of the DC-DC converter (2);
a current control (12) configured to determine a second control variable (R2) for the DC-DC converter (2) using a current control variable(1_target) and a momentary current value(1_dc) of the DC-DC converter (2);
a pilot device (13) configured to determine a third control variable (R3) using the target value (U_target) for the output voltage of the DC-DC voltage converter (2) and a filtered measured value (U_in1) for the input voltage of the DC-DC voltage converter (2); and
a control device (14) configured to control the DC-DC converter (2) using a combination of the first control variable (R1), the second control variable (R2) and the third control variable (R3) in a first operating mode, and
to control the DC-DC converter (2) using a combination of the first control variable (R1), the second control variable (R2) and a measured value (U_in2) for the input voltage of the DC-DC converter (2) in a second operating mode.

2. The DC-DC converter device (1) according to claim 1, wherein the control device (14) is configured to control the DC-DC converter (2) further in the second operating mode using a measured value for an output current of the DC-DC converter (2).

3. The DC-DC converter device (1) according to claim 1, wherein the pilot device (13) is configured to provide a control signal (F2) to the control device (14), and
wherein the control device (14) is configured to set either the first operating mode or the second operating mode using the control signal (F2) from the pilot device (13).

4. The DC-DC voltage converter device (1) according to claim 1, wherein the control device (14) is configured to detect the measured value (U_in2) for the input DC voltage at a sampling rate that is higher than a sampling rate for detecting the measured value (U_in1) of the input DC voltage for the pilot device (13).

5. The DC-DC voltage converter device (1) according to claim 4, wherein the control device (14) is configured to detect frequency components in the DC input voltage up to at least 10 kHz.

6. The DC-DC voltage converter device (1) according to claim 1, wherein the DC voltage converter device (1) is configured to perform the determination of the first control variable (R1), the second control variable (R2) and the third control variable (R3) as well as controlling the DC-DC voltage converter (2) in the first operating mode using a first computing device, wherein the first computing device comprises at least one microcontroller, and
wherein the DC-DC voltage converter device (1) is configured to perform the control of the DC-DC voltage converter (2) in the second operating mode further using a second computing device (15), wherein the second computing device (15) is configured to receive and process the measured value (U_in2) for the input voltage of the DC-DC voltage converter (2).

7. The DC-DC voltage converter device (1) according to claim 6, wherein the second computing device (15) comprises a multi-channel sequencer.

8. The DC-DC converter device (1) according to claim 1, claims 1 to 7, wherein the DC-DC converter device (1) comprises multiple DC-DC converters (2),
wherein a separate current control (12) and a separate control device (14) is provided for each DC-DC converter (2) of the DC-DC converter device (1), and
wherein a common voltage control (11) and a common pilot device (13) is provided for all DC-DC converters (2) of the DC-DC converter device (1).

9. A method of operating a DC-DC converter device (1) with at least one DC-DC converter (2), with the steps of:
determining (S1) a first control variable (R1) for the DC-DC converter (2) using a target value (U_target) for the output voltage of the DC-DC converter (2) and a measured value (U_out) for the output voltage of the DC-DC converter (2);
determining (S2) a second control variable (R2) for the DC-DC converter (2) using a current control variable (1_target) and a momentary current value (1_dc) of the DC-DC converter (2);
determining (S3) a third control variable (R3) using a target value (U_target) for the output voltage of the DC-DC converter (2) and a filtered measured value (U_in1) for the input voltage of the DC-DC converter (2); and
controlling (S4) the DC-DC converter (2) in a first operating mode using a combination of the first control variable,
the second control variable and the third control variable or controlling (S 5) the DC-DC voltage converter (2) in a second operating mode using a combination of the first control variable (R1), the second control variable (R 2) and a measured value (U_in2) for the input voltage of the DC-DC voltage converter (2).

10. The method of claim 9, wherein the DC-DC converter (2) is initially controlled in the first operating mode after initialization, and
is subsequently switched to the second operating mode after a quasi-stationary operating state has been set in the DC-DC converter (2).
